(19) United States
(12) Patent Application Publication
(10) Pub. No.: US 2009/0200668 A1
(43) Pub. Date: Aug. 13, 2009

(54) INTERCONNECT STRUCTURE WITH HIGH LEAKAGE RESISTANCE

(75) Inventors: Chih-Chao Yang, Glenmont, NY (US); Satya V. Nitta, Poughquag, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/027,677

(22) Filed: Feb. 7, 2008

(51) Int. Cl. H01L 23/48; H01L 21/4763

(52) U.S. Cl. 257/751; 438/622; 257/E23.01; 257/E21.495

(57) ABSTRACT

An interconnect structure is provided in which the conductive feature (i.e., conductive material) is not coplanar with the upper surface of the dielectric material, but instead the conductive material is recessed below an upper surface of the dielectric material. In addition to being recessed below the upper surface of the dielectric material, the conductive material of the interconnect structure is surrounded on all sides (i.e., sidewall surfaces, upper surface and bottom surface) by a diffusion barrier material. Unlike prior art interconnect structures, the barrier material located on the upper surface of the recessed conductive material is located with an opening including the recessed conductive material.

### FIELD OF THE INVENTION

The present invention relates to a semiconductor structure, and a method of fabricating the same. More particularly, the present invention relates to a semiconductor interconnect structure having a high leakage resistance as well as no metallic residues (e.g., defects) present at the upper surface of the interconnect dielectric. The present invention also provides a method in which the leakage resistance within an interconnect structure is improved, while avoiding the formation of metallic residues (e.g., defects) at the upper surface of the interconnect dielectric.

### BACKGROUND OF THE INVENTION

Generally, semiconductor devices include a plurality of circuits that form an integrated circuit (IC) fabricated on a semiconductor substrate. A complex network of signal paths will normally be routed to connect the circuit elements distributed on the surface of the substrate. Efficient routing of these signals across the device requires formation of multilevel or multilayered schemes, such as, for example, single or dual damascene wiring structures. The wiring structure typically includes copper, Cu, or a Cu alloy since Cu-based interconnects provide higher speed signal transmission between large numbers of transistors on a complex semiconductor chip as compared with aluminum, Al,-based interconnects.

Within a typical interconnect structure, metal vias run perpendicular to the semiconductor substrate and metal lines run parallel to the semiconductor substrate. Further enhancement of the signal speed and reduction of signals in adjacent metal lines (known as “crosstalk”) are achieved in today's IC product chips by embedding the metal lines and metal vias (e.g., conductive features) in a dielectric material having a dielectric constant of less than 4.0.

In current semiconductor interconnect structures, time-dependent-dielectric-breakdown (TDDB) has been identified as one of the major reliability concerns for future interconnect structures that include Cu-based metallurgy and low k dielectric materials. By “TDDB” it is meant, that overtime the dielectric material of the interconnect structure begins to fail. The failure of the dielectric material may be caused by intrinsic means or by defects that are formed on the surface of the interconnect dielectric material during the course of preparing the interconnect structure.

Leakage of metallic ions, particularly Cu ions, along the interconnect dielectric surface has been identified as the major intrinsic failure mechanism that attributes to TDDB. FIG. 1A is a prior art interconnect structure 10 which illustrates this intrinsic leakage phenomenon. Specifically, the prior art interconnect structure includes a dielectric material 12 having a Cu feature 14 embedded therein. The Cu feature 14 is typically separated from the dielectric material 14 by a diffusion barrier 16. A dielectric capping layer 18 is present on the surface of the dielectric material 14, the diffusion barrier 16 and the Cu feature 14. In FIG. 1A, the arrows designate the leakage (diffusion) of Cu ions from the conductive feature 14 which occurs along the upper surface of the interconnect structure as shown. Overtime, this leakage of Cu ions results in TDDB as well as failure of the devices within the interconnect structure.

Another contributor to TDDB, which is illustrated in FIG. 1B, is defect related. Specifically, FIG. 1B is another prior art interconnect structure 10′ including the components as shown in FIG. 1A in which Cu residues (e.g., defects) 20 are present at the interface between the upper surface of the dielectric material 12 and the dielectric capping layer 18. The Cu residues 20 are formed during the formation of the Cu features 14 (i.e., deposition and planarization of Cu within an opening formed into the dielectric material 12). Post planarization Cu residues, which provide defects at the surface of the dielectric material, are one of the root causes of time-dependent-dielectric-breakdown (TDDB) failure.

It is noted that although Cu is specifically mentioned with respect to the prior art interconnect structures mentioned above, the above leakage and defect problems occur (although at different rates and extents) with other types of conductive metals such as, for example Al and W.

In view of leakage problem illustrated in FIG. 1A, and the residues problem illustrated in FIG. 1B, there is a continued need for providing an interconnect structure in which metallic leakage, particularly, Cu ion diffusion, and metallic residues, particularly Cu residues, can both be reduced or completely eliminated from an interconnect structure.

### SUMMARY OF THE INVENTION

The present invention provides an interconnect structure that has high leakage resistance and no metallic residues present at the upper dielectric surface of a particular interconnect level of an interconnect structure. As such, the inventive interconnect structure exhibits an improved time-dependent-dielectric-breakdown (TDDB) as compared to prior art interconnect structures.

In the inventive interconnect structure, the conductive feature (i.e., conductive material) is not coplanar with the upper surface of the dielectric material, but instead the conductive material is recessed below an upper surface of the dielectric material. In addition to being recessed below the upper surface of the dielectric material, the conductive material of the inventive interconnect structure is surrounded on all sides (i.e., sidewall surfaces, upper surface and bottom surface) by a diffusion barrier material. The sidewall surfaces and the bottom surface of the recessed conductive material are lined with a U-shaped diffusion barrier. The upper surface of the recessed conductive material is lined with an insulating or metallic layer. Edge portions of the insulating or metallic layer lining the upper surface of the conductive material are in contact with upper sidewall surfaces of the U-shaped diffusion barrier or, if present, an optional plating seed layer. The insulating or metallic layer lining the upper surface of the recessed conductive material both have diffusion barrier properties. Since the recessed conductive material is completely surrounded by a diffusion barrier material, leakage of metallic ions at the surface of the dielectric material is substantially, if not completely, eliminated.

Unlike prior art interconnect structures, the barrier material located on the upper surface of the recessed conductive material is located with an opening including the recessed conductive material in the present inventive interconnect structure. In prior art interconnect structures, any barrier layer formed atop the conductive feature (i.e. conductive material) is present atop, e.g., spanning, the opening, not within the opening containing the conductive material as is the case in the inventive interconnect structure.

It is further noted that in the present interconnect structure there is no direct contact between the recessed conductive material and the dielectric material and no planarization of the conductive material extending on the surface of the dielectric material is employed as such no conductive residues are formed at the upper surface of the interconnect dielectric material as is the case with prior art interconnect structures. The above features have a significant benefit on substantially reducing or even eliminating conductive metal residues (e.g., defects) on the dielectric surface. As such, the present invention provides a reliable and technology extendible interconnect structure that can be fabricated in high volumes.

In general terms, the interconnect structure of the present invention comprises:
a dielectric material having a dielectric constant of about 4.0 or less;
a conductive material having sidewall surfaces, a bottom surface and an upper surface embedded within said dielectric material, wherein said upper surface of said conductive material is located beneath an upper surface of the dielectric material;
at least a U-shaped diffusion barrier located on said sidewall surfaces and said bottom surface of said conductive material; and
an insulating or metallic layer having diffusion barrier properties located on said upper surface of said conductive material, said insulating or metallic layer having diffusion barrier properties having edge portions that are in contact with upper sidewall surfaces of at least said U-shaped barrier.

In some embodiments of the interconnect structure of the present invention, a dielectric capping layer is also present and is located on the upper surface of the dielectric material and an upper surface of the insulating or metallic layer having diffusion barrier properties. In such an embodiment, the dielectric capping layer may comprise one of SiC, Si₄NH₃, SiO₂, a carbon doped oxide, and a nitrogen and hydrogen doped silicon carbide SiC(N,H).

In a further embodiment of the inventive interconnect structure, the dielectric material, which may be porous or non-porous, may comprise one of SiO₂, a silsesquioxane, a C doped oxide including atoms of Si, C, O and H, and a thermosetting polyarylene ether.

In a yet further embodiment of the present invention, the U-shaped diffusion barrier within the inventive interconnect structure may comprise Ta, TaN, Ti, TiN, Ru, RuN, RuTa, RuTaN, W or WN.

In another embodiment of the inventive interconnect structure, a U-shaped plating seed layer is also present and is located between the at least one conductive material and the U-shaped diffusion barrier. In this instance, the edge portions of the insulating or metallic layer are in direct contact with the upper sidewall surface of the U-shaped plating seed layer. The U-shaped plating seed layer is used when the conductive material is formed by a plating process. When present, the U-shaped plating seed layer may comprise Cu, a Cu alloy, Ir, an Ir alloy, Ru or a Ru alloy.

In still another embodiment of the inventive interconnect structure, the at least one conductive material may comprises Cu, W or Al in pure or alloyed form.

In a preferred embodiment of the invention, an interconnect structure is provided that comprises:
a dielectric material having a dielectric constant of about 4.0 or less;
a copper-containing conductive material having sidewall surfaces, a bottom surface and an upper surface embedded within said dielectric material, wherein said upper surface of said copper-containing conductive material is located beneath an upper surface of the dielectric material;
at least a U-shaped diffusion barrier located on said sidewall surfaces and said bottom surface of said copper-containing conductive material; and
an insulating or metallic layer having diffusion barrier properties located on said upper surface of said conductive material, said insulating or metallic layer having diffusion barrier properties having edge portions that are in contact with at least upper sidewall surfaces of at least said U-shaped barrier.

In some embodiments of the preferred interconnect structure of the present invention, a dielectric capping layer is also present and is located on the upper surface of the dielectric material and an upper surface of the insulating or metallic layer having diffusion barrier properties. In such an embodiment, the dielectric capping layer may comprise one of SiC, Si₄NH₃, SiO₂, a carbon doped oxide, and a nitrogen and hydrogen doped silicon carbide SiC(N,H).

In a further embodiment of the preferred interconnect structure, the dielectric material, which may be porous or non-porous, may comprise one of SiO₂, a silsesquioxane, a C doped oxide including atoms of Si, C, O and H, and a thermosetting polyarylene ether.

In a yet further embodiment of the preferred interconnect structure, the U-shaped diffusion barrier within the inventive interconnect structure may comprise Ta, TaN, Ti, TiN, Ru, RuN, RuTa, RuTaN, W or WN.

In another embodiment of the preferred interconnect structure, a U-shaped plating seed layer is also present and is located between the conductive material and the U-shaped diffusion barrier. In this instance, the edge portions of the insulating or metallic layer are in direct contact with the upper sidewall surface of the U-shaped plating seed layer. The U-shaped plating seed layer is used when the copper-containing conductive material is formed by a plating process. when present the U-shaped plating seed layer may comprise Cu, a Cu alloy, Ir, an Ir alloy, Ru or a Ru alloy.

In addition to the interconnect structures mentioned above, the present invention also provides a method of fabricating the same
forming at least one opening into a dielectric material having a dielectric constant of about 4.0 or less, said dielectric material having a patterned hard mask located on an upper surface thereof;
lining the at least one opening and the patterned hard mask with a diffusion barrier;
partially filling the at least one opening with a conductive material, said conductive material having an upper surface that is located beneath an upper surface of said dielectric material;
forming an insulating or metallic material having diffusion barrier properties within the at least one opening and on the upper surface of said conductive material as well as atop the diffusion barrier lining the patterned hard mask; and
removing a portion of the insulating or metallic material having diffusion barrier properties and the diffusion barrier and the patterned hard mask that lay above the upper surface of the dielectric material, while maintaining another portion of the insulating or metallic material having diffusion barrier properties within said at least one opening and forming a U-shaped diffusion barrier within said at least one opening, wherein said another portion of the insulating or metallic material having diffusion barrier properties has an upper surface that is coplanar with the upper surface of the dielectric material, and said conductive material is completely surrounded by the U-shaped diffusion barrier located on sidewall surfaces and a bottom surface of said conductive material, and said another portion of the insulating material having diffusion barrier properties located on the upper surface of the conductive material.

In one embodiment of the inventive method, a dielectric capping layer is formed on the upper surface of the dielectric material and on an upper surface of the another portion of the insulating or metallic material having diffusion barrier properties that remains in the at least one opening. When present, the dielectric capping layer may comprise one of SiC, Si₄NH₃, SiO₂, a carbon doped oxide, and a nitrogen and hydrogen doped silicon carbide SiC(N,H).

In another embodiment of the inventive method, the diffusion barrier may comprises Ta, TaN, Ti, TiN, Ru, RuN, RuTa, RuTaN, W or WN, and is formed by chemical vapor deposition, plasma enhanced chemical vapor deposition, atomic layer deposition, physical vapor deposition, sputtering, chemical solution deposition and plating.

In yet another embodiment of the inventive method, a plating seed layer is formed between the conductive material and the diffusion barrier, and the plating seed layer may comprise Cu, a Cu alloy, Ir, an Jr alloy, Ru or a Ru alloy. In embodiments wherein a plating seed layer is employed, the plating seed layer is formed by chemical vapor deposition, plasma enhanced chemical vapor deposition, atomic layer deposition or physical vapor deposition.

In a further embodiment of the inventive method, the conductive material may comprise Cu, W or Al in pure or alloyed form.

In a still further embodiment of the inventive method, the partially filing the at least one opening with the conductive material comprises a deposition process selected from chemical vapor deposition, sputtering, chemical solution deposition and plating.

In an even further embodiment of the present invention, the partially filing the at least one opening with the conductive material comprises completely filling the at least one opening with the conductive material and recessing.

In still an even further embodiment of the inventive method, the removing step comprises chemical mechanical polishing.

### BRIEF DESCRIPTION OF THE DRAWINGS

FIGS. 1A-1B are pictorial representations (through cross sectional views) depicting prior art interconnect structures. FIG. 1A shows Cu leakage, while FIG. 1B shows Cu residues.

FIGS. 2A-2G are pictorial representations (through cross sectional views) depicting the basic process steps that are employed in the present invention in fabricating a highly reliable and technology extendible interconnect structure having a high leakage resistance and no metallic residues present at the surface of the dielectric material.

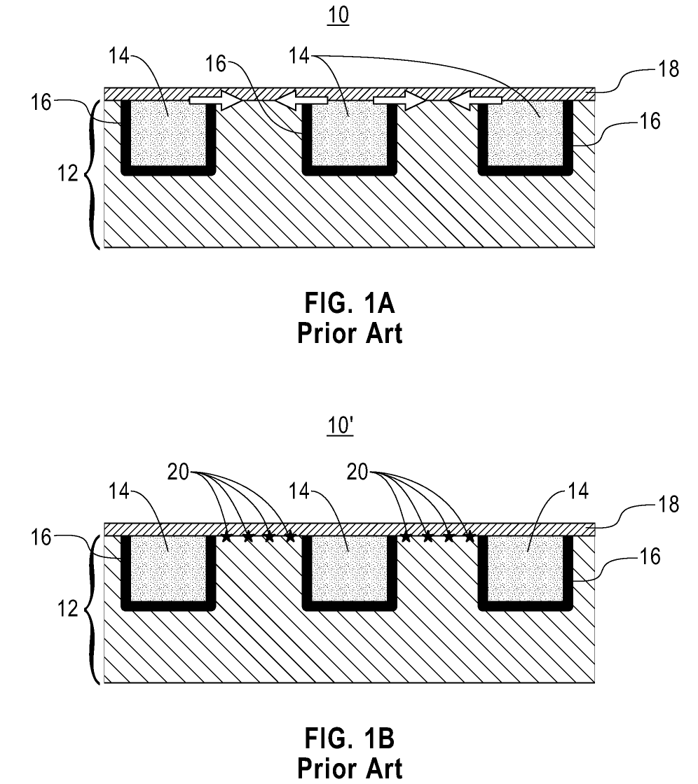

### DETAILED DESCRIPTION OF THE INVENTION

The present invention, which provides an interconnect structure having high leakage resistance and no metallic residues present at the surface of the dielectric material and a method of fabricating the same, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As stated above, the present invention provides an interconnect structure having high leakage resistance and no metallic residues present at the surface of the dielectric material and a method of fabricating the same. The inventive interconnect structure exhibits improved TDDB than prior art invention structures.

In the inventive interconnect structure, the conductive feature (i.e., conductive material) is not coplanar with the upper surface of the dielectric material, but instead the conductive material is recessed below an upper surface of the dielectric material. In addition to being recessed below the upper surface of the dielectric material, the conductive material of the inventive interconnect structure is surrounded on all sides (i.e., sidewall surfaces, upper surface and bottom surface) by a diffusion barrier material. The sidewall surfaces and the bottom surface of the recessed conductive material within the opening are lined with a U-shaped diffusion barrier. The upper surface of the recessed conductive material is lined with an insulating or metallic layer, both of which have diffusion barrier properties. Edge portions of the insulating or metallic layer lining the upper surface of the conductive material are in contact with upper sidewall surfaces of the U-shaped diffusion barrier or, if present, an optional U-shaped plating seed layer.

It is further noted that in the present application there is no direct contact between the recessed conductive material and the dielectric material and no planarization of the conductive material extending on the surface of the interconnect dielectric is employed as such no conductive residues are formed at the upper surface of the interconnect structure as is the case with prior art interconnect structures. The above features have a significant benefit on reducing conductive metal residues (e.g., defects) on the dielectric surface.

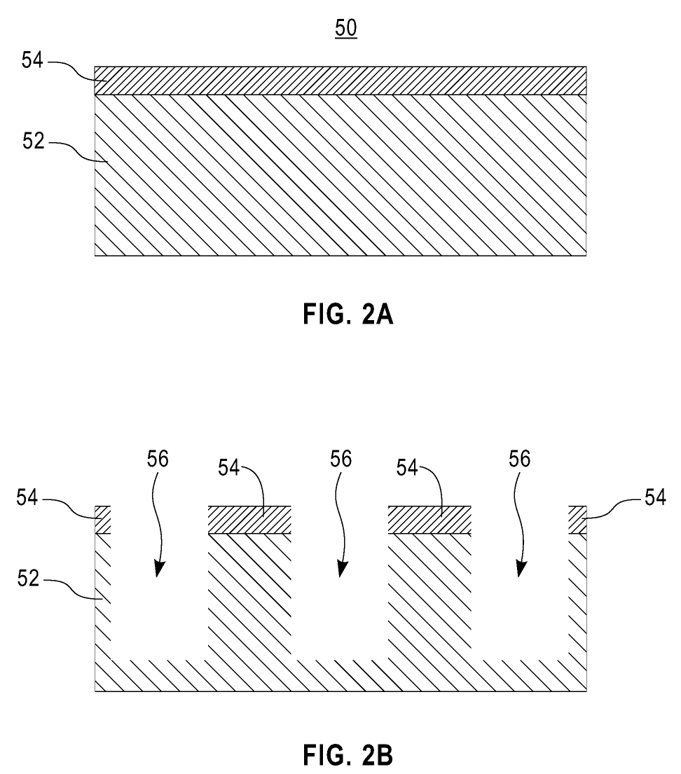

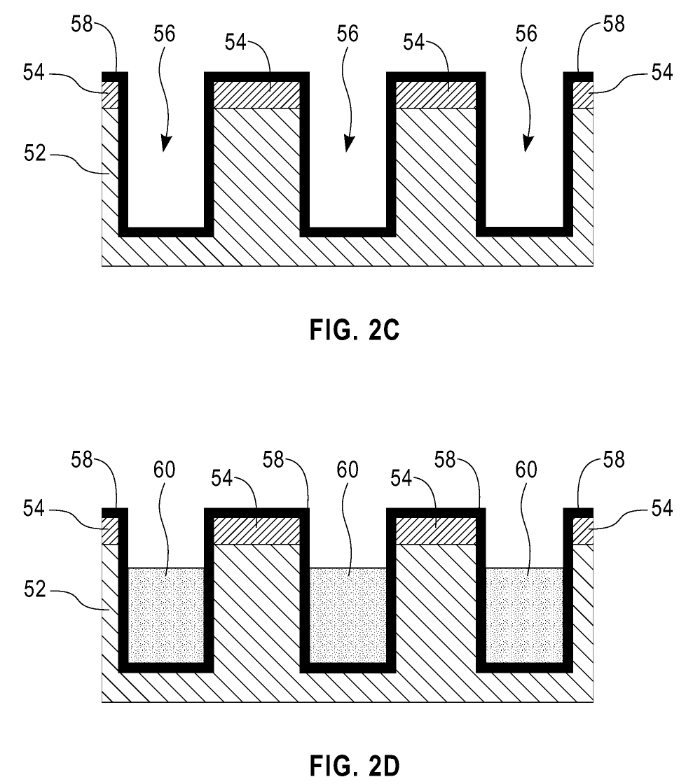

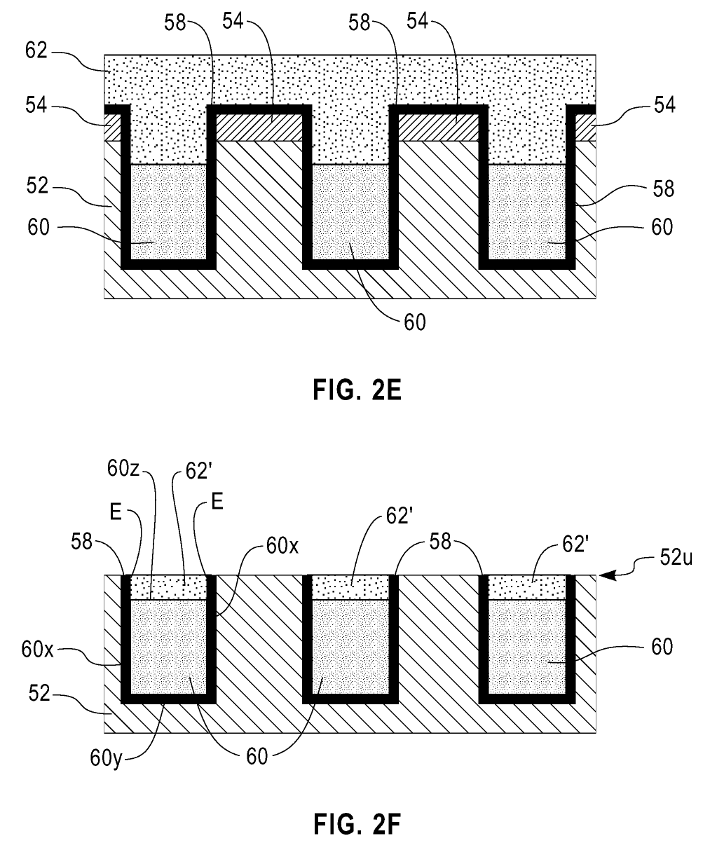

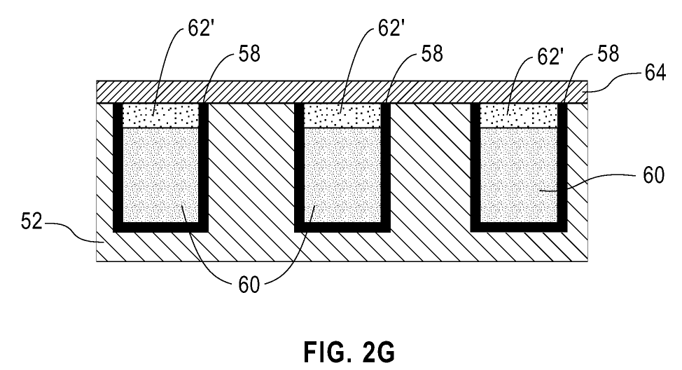

Reference is now made to FIGS. 2A-2G which illustrate the basic processing steps that are used in forming the semiconductor interconnect structure of the present invention. FIG. 2A illustrates an initial structure 50 that comprises a dielectric material 52 and a hard mask 54 located on a surface of the dielectric material 52.

The initial structure 50, i.e., the dielectric material 52, may be located upon a substrate (not shown in the drawings of the present application). The substrate, which is not shown, may comprise a semiconducting material, an insulating material, a conductive material or any combination thereof. When the substrate is comprised of a semiconducting material, any semiconductor such as Si, SiGe, SiGeC, SiC, Ge alloys, GaAs, InAs, InP and other III/V or II/VI compound semiconductors may be used. In addition to these listed types of semiconducting materials, the present invention also contemplates cases in which the semiconductor substrate is a layered semiconductor such as, for example, Si/SiGe, Si/SiC, silicon-on-insulators (SOIs) or silicon germanium-on-insulators (SGOIs).

When the substrate is an insulating material, the insulating material can be an organic insulator, an inorganic insulator or a combination thereof including multilayers. When the substrate is a conducting material, the substrate may include, for example, polySi, an elemental metal, alloys of elemental metals, a metal silicide, a metal nitride or combinations thereof including multilayers. When the substrate comprises a semiconducting material, one or more semiconductor devices such as, for example, complementary metal oxide semiconductor (CMOS) devices can be fabricated thereon. When the substrate comprises a combination of an insulating material and a conductive material, the substrate may represent a first interconnect level of a multilayered interconnect structure.

The dielectric material 52 comprises any interlevel or intralevel dielectric including inorganic dielectrics or organic dielectrics. The dielectric material 52 may be porous or non-porous. Some examples of suitable dielectrics that can be used as the dielectric material 52 include, but are not limited to: Sio₂, silsesquioxanes, C doped oxides (i.e., organosilicates) that include atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like.

The dielectric material 52 typically has a dielectric constant that is about 4.0 or less, with a dielectric constant of about 2.8 or less being even more typical. All dielectric constants mentioned herein are relative to a vacuum, unless otherwise noted. These dielectrics generally have a lower parasitic cross talk as compared with dielectric materials that have a higher dielectric constant than 4.0. The thickness of the dielectric material 52 may vary depending upon the dielectric material used as well as the exact number of dielectrics layers within the dielectric material 52. Typically, and for normal interconnect structures, the dielectric material 52 has a thickness from about 50 to about 1000 nm.

As mentioned above, the initial structure 50 also includes a hard mask 54 located on an upper surface of dielectric material 52. The hard mask 54 comprises an oxide, a nitride, an oxynitride or any multilayered combination thereof. In one embodiment, the hard mask 54 is an oxide such as silicon dioxide, while in another embodiment the hard mask 54 is a nitride such as silicon nitride.

The hard mask 54 is formed utilizing a conventional deposition process including, for example, chemical vapor deposition (CVD), plasma enhanced chemical vapor deposition (PECVD), chemical solution deposition, evaporation, and physical vapor deposition (PVD). Alternatively, the hard mask 54 may be formed by one of thermal oxidation, and thermal nitridation.

The thickness of the hard mask 54 employed in the present invention may vary depending on the material of the hard mask itself as well as the techniques used in forming the same. Typically, the hard mask 54 has a thickness from about 5 to about 100 nm, with a thickness from about 10 to about 80 nm being even more typical.

Next, and as shown in FIG. 2B, at least one opening 56 is formed into the hard mask 54 and the dielectric material 54 utilizing lithography and etching. The lithographic process includes forming a photoresist (not shown) atop the hard mask 54, exposing the photoresist to a desired pattern of radiation and developing the exposed photoresist utilizing a conventional resist developer. The etching process includes a dry etching process (such as, for example, reactive ion etching, ion beam etching, plasma etching or laser ablation), and/or a wet chemical etching process. Typically, reactive ion etching is used in providing the at least one opening 56. Typically, the etching process includes a first pattern transfer step in which the pattern provided to the photoresist is transferred to the hard mask 54, the patterned photoresist is then removed by an ashing step, and thereafter, a second pattern transfer step is used to transfer the pattern from the patterned hard mask into the underlying dielectric material.

The depth of the at least one opening 56 that is formed into the dielectric material 54 (measured from the upper surface of the dielectric material to the bottom wall of the opening) may vary and it not critical to the present application. In some embodiments, the at least one opening 56 may extend entirely through the dielectric material. In yet other embodiments, the at least one opening 56 stops within the dielectric material 52 itself. In yet further embodiments, different depth openings can be formed.

It is further observed that the at least one opening 56 may be a via opening, a line opening, and/or combined via/line opening. In FIG. 2B, and by way of an example, each of the openings is shown as line openings.

Next, as shown in FIG. 2C, a diffusion barrier 58 is formed on all exposed surfaces of the structure shown in FIG. 2B including within the at least one opening (i.e., on sidewalls and the bottom wall of each of the openings) and along the upper surface of remaining hard mask 54.

The diffusion barrier 58 comprises Ta, TaN, Ti, TiN, Ru, RuN, RuTa, RuTaN, W, WN or any other material that can serve as a barrier to prevent a conductive material from diffusing there through. The thickness of the diffusion barrier 58 may vary depending on the deposition process used as well as the material employed. Typically, the diffusion barrier 58 has a thickness from about 2 to about 50 nm, with a thickness from about 5 to about 20 nm being more typical.

The diffusion barrier 58 is formed by a deposition process including, for example, chemical vapor deposition (CVD), plasma enhanced chemical vapor deposition (PECVD), atomic layer deposition (ALD), physical vapor deposition (PVD), sputtering, chemical solution deposition and plating.

In some embodiments, an optional plating seed layer (not specifically shown within FIG. 2C) can be formed on the surface of the diffusion barrier 58. In cases in which the conductive material to be subsequently and directly formed on the diffusion barrier 58, the optional plating seed layer is not needed. The optional plating seed layer is employed to selectively promote subsequent electroplating of a pre-selected conductive metal or metal alloy. The optional plating seed layer may comprise Cu, a Cu alloy, Ir, an Ir alloy, Ru, a Ru alloy (e.g., TaRu alloy) or any other suitable noble metal or noble metal alloy having a low metal-plating overpotential. Typically, Cu or a Cu alloy plating seed layer is employed, when a Cu metal is to be subsequently formed within the openings 56.

The thickness of the optional seed layer may vary depending on the material of the optional plating seed layer as well as the technique used in forming the same. Typically, the optional plating seed layer has a thickness from about 2 to about 80 nm.

The optional plating seed layer can be formed by a conventional deposition process including, for example, CVD, PECVD, ALD, and PVD.

A conductive material 60 (forming a conductive feature within the dielectric material 52) is partially formed within the at least one opening 56 that is now lined with at least diffusion barrier providing the structure shown, for example, in FIG. 2D. A time-controlled process is performed to result in the partially formed structure. The conductive material 60 may comprise polySi, SiGe, a conductive metal, an alloy comprising at least one conductive metal, a conductive metal silicide or combinations thereof. Preferably, the conductive material 60 is a conductive metal such as Cu, W or Al, with Cu or a Cu alloy (such as AlCu) being highly preferred in the present invention.

The conductive material 60 may be formed by partially filling the at least one opening 56 or by fully filling the at least one opening 56 and then recessing the conductive material 60 to a level below the upper surface of the dielectric material 52. Any conventional deposition process including chemical vapor deposition (CVD), plasma enhanced chemical vapor deposition (PECVD), sputtering, chemical solution deposition or plating that fills the at least one opening from the bottom upwards can be used. Preferably, a bottom-up plating process is employed.

When a recess step is employed, an etching process that selectively removes portions of the conductive material 60 is used to provide partial filling of the at least one opening 56 in the dielectric material 52.

Next, a planarization stop layer 62 is formed within the remaining portion of the at least one opening 56 as well as atop the diffusion barrier 58 (or optional metal seed layer) that extends outside of the at least one opening 56. The resultant structure including the planarization stop layer 62 is shown, for example, in FIG. 2E. The planarization stop layer 62 comprises any insulating material such as, for example, silicon carbide, silicon nitride, and/or a nitrogen and hydrogen doped silicon carbide or any metallic material such as, for example, Ta, Ru, Ir, W, Co, Ti and/or Rh in pure, alloyed or nitrided forms which have diffusion barrier properties. As such, the planarization stop layer 62 may be referred to as an insulating or metallic material having diffusion barrier properties.

The planarization stop layer 62 is formed by a conventional deposition process including, but not limited to CVD, PECVD, evaporation, chemical solution deposition, sputtering, and physical vapor deposition (PVD).

Next, and as is illustrated in FIG. 2F, a planarization process such as, for example, chemical mechanical polishing (CMP) and/or grinding, is employed to remove portions of the planarization stop layer 62 that extend above the mouth of the at least one opening 56. It is noted that during the planarization step the diffusion barrier and the hard mask are removed from atop the upper, horizontal surface of the dielectric material 52. As such, the planarization process provides a conductive material 60 that is completely surrounded by a U-shaped diffusion barrier (on the sidewall surfaces and bottom surface) and by the remaining portion of planarization stop layer 62′ that was not removed during this step of the present invention. The remaining portion of the planarization stop layer is located within the at least one opening and it has an upper surface that is coplanar with the upper surface of the dielectric material 52.

It is emphasized that FIG. 2F illustrates the inventive interconnect of the present invention. As shown, the inventive interconnect structure includes dielectric material 52 having a dielectric constant of about 4.0 or less; and a conductive material 60 having sidewall surfaces 60X, a bottom surface 60Y and an upper surface 60Z embedded within dielectric material 52, wherein the upper surface 60Z of the conductive material 60 is located beneath the upper surface 52U of the dielectric material 52. The inventive interconnect structure also includes at least a U-shaped diffusion barrier 58 located on said sidewall surfaces 60X and said bottom surface 60Y of the conductive material 60. The inventive interconnect structure also includes an insulating or metallic layer having diffusion barrier properties 62′ located on the upper surface 60Z of the conductive material 60, said insulating or metallic layer having diffusion barrier properties 62′ having edge portions E that are in contact with upper sidewall surfaces of at least said U-shaped barrier.

FIG. 2G illustrates an optional embodiment in which a dielectric capping layer 64 is formed on the exposed surfaces of the structure shown in FIG. 2F. The dielectric capping layer 64 comprises any suitable dielectric capping material such as, for example, SiC, Si₄NH₃, SiO₂, a carbon doped oxide, a nitrogen and hydrogen doped silicon carbide SiC(N,H) or multilayers thereof. Any conventional deposition process such as, for example, chemical vapor deposition, plasma enhanced chemical vapor deposition, chemical solution deposition, evaporation, and atomic layer deposition may be used in forming the optional dielectric capping layer 64. The thickness of the dielectric capping layer 64 may vary depending on the technique used to form the same as well as the material make-up of the layer. Typically, the dielectric capping layer 64 has a thickness from about 15 to about 100 nm, with a thickness from about 25 to about 45 nm being more typical.

It is noted that during the method of the invention, no direct contact between the conductive material 60 and the dielectric material 52 is made and no planarization of a conductive material extending on the surface of the dielectric is employed as such no conductive residues are formed. The above features have a significant benefit on reducing conductive metal residues (e.g., defects) on the dielectric surface. As such, the inventive method provides a reliable and technology extendible interconnect structure that can be fabricated in high volumes.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. An interconnect structure comprising:
a dielectric material having a dielectric constant of about 4.0 or less;
a conductive material having sidewall surfaces, a bottom surface and an upper surface embedded within said dielectric material wherein said upper surface of said conductive material is located beneath an upper surface of the dielectric material;
at least a U-shaped diffusion barrier located on said sidewall surfaces and said bottom surface of said conductive material; and
an insulating or metallic layer having diffusion barrier properties located on said upper surface of said conductive material, said insulating or metallic layer having diffusion barrier properties having edge portions that are in contact with upper sidewall surfaces of at least said U-shaped barrier.

2. The interconnect structure of claim 1 further comprising a dielectric capping layer located on said upper surface of said dielectric material and an upper surface of said insulating or metallic layer having diffusion barrier properties.

3. The interconnect structure of claim 2 wherein said dielectric capping layer comprises one of SiC, Si₄NH₃, SiO₂, a carbon doped oxide, and a nitrogen and hydrogen doped silicon carbide SiC(N,H).

4. The interconnect structure of claim 1 wherein said dielectric material comprises one of SiO₂, a silsesquioxane, a C doped oxide including atoms of Si, C, O and H, and a thermosetting polyarylene ether.

5. The interconnect structure of claim 1 wherein said U-shaped diffusion barrier comprises Ta, TaN, Ti, TiN, Ru, RuN, RuTa, RuTaN, W or WN.

6. The interconnect structure of claim 1 further comprises a U-shaped plating seed layer located between said conductive material and said U-shaped diffusion barrier, said U-shaped plating seed layer comprises Cu, a Cu alloy, Ir, an Ir alloy, Ru or a Ru alloy.

7. The interconnect structure of claim 1 wherein said conductive material comprises Cu, W or Al in pure or alloyed form.

8. The interconnect structure of claim 1 wherein said insulating or metallic material having diffusion barrier properties comprises one of silicon carbide, silicon nitride, a nitrogen and hydrogen doped silicon carbide, and a metallic material selected from Ta, Ru, Ir, W, Co, Ti and Rh in pure, alloyed or nitrided forms.

9. An interconnect structure comprising:
a dielectric material having a dielectric constant of about 4.0 or less;
a copper-containing conductive material having sidewall surfaces, a bottom surface and an upper surface embedded within said dielectric material, wherein said upper surface of said copper-containing conductive material is located beneath an upper surface of the dielectric material;
at least a U-shaped diffusion barrier located on said sidewall surfaces and said bottom surface of said copper-containing conductive material; and
an insulating or metallic layer having diffusion barrier properties located on said upper surface of said conductive material, said insulating or metallic layer having diffusion barrier properties having edge portions that are in contact with at least upper sidewall surfaces of at least said U-shaped barrier.

10. The interconnect structure of claim 9 further comprising a dielectric capping layer located on said upper surface of said dielectric material and an upper surface of said insulating or metallic layer having diffusion barrier properties.

11. The interconnect structure of claim 10 wherein said dielectric capping layer comprises one of SiC, Si₄NH₃, SiO₂, a carbon doped oxide, and a nitrogen and hydrogen doped silicon carbide SiC(N,H).

12. The interconnect structure of claim 9 wherein said dielectric material comprises one of SiO₂, a silsesquioxane, a C doped oxide including atoms of Si, C, O and H, and a thermosetting polyarylene ether.

13. The interconnect structure of claim 9 wherein said U-shaped diffusion barrier comprises Ta, TaN, Ti, TiN, Ru, RuN, RuTa, RuTaN, W or WN.

14. The interconnect structure of claim 9 further comprises a U-shaped plating seed layer located between said conductive material and said U-shaped diffusion barrier, said U-shaped plating seed layer comprises Cu, A Cu alloy, Ir, an Ir alloy, Ru or a Ru alloy.

15. The interconnect structure of claim 9 wherein said insulating or metallic material having diffusion barrier properties comprises one of silicon carbide, silicon nitride, a nitrogen and hydrogen doped silicon carbide and a metallic material selected from Ta, Ru, Ir, W, Co, Ti and Rh in pure, alloyed or nitrided forms.

16. A method of forming an interconnect structure comprising:
forming at least one opening into a dielectric material having a dielectric constant of about 4.0 or less, said dielectric material having a patterned hard mask located on an upper surface thereof;
lining the at least one opening and the patterned hard mask with a diffusion barrier;
partially filling the at least one opening with a conductive material, said conductive material having an upper surface that is located beneath an upper surface of said dielectric material;
forming an insulating or metallic material having diffusion barrier properties within the at least one opening and on the upper surface of said conductive material as well as atop the diffusion barrier lining the patterned hard mask; and
removing a portion of the insulating or metallic material having diffusion barrier properties and the diffusion barrier and the patterned hard mask that lay above the upper surface of the dielectric material, while maintaining another portion of the insulating or metallic material having diffusion barrier properties within said at least one opening and forming a U-shaped diffusion barrier within said at least one opening, wherein said another portion of the insulating or metallic material having diffusion barrier properties has an upper surface that is coplanar with the upper surface of the dielectric material, and said conductive material is completely surrounded by the U-shaped diffusion barrier located on sidewall surfaces and a bottom surface of said conductive material, and said another portion of the insulating material having diffusion barrier properties located on the upper surface of the conductive material.

17. The method of claim 16 further comprising forming a dielectric capping layer on said upper surface of said dielectric material and on an upper surface of the another portion of the insulating or metallic material having diffusion barrier properties that remains in said at least one opening.

18. The method of claim 16 wherein said diffusion barrier comprises Ta, TaN, Ti, TiN, Ru, RuN, RuTa, RuTaN, W or WN.

19. The method of claim 18 wherein said diffusion barrier is formed by chemical vapor deposition, plasma enhanced chemical vapor deposition, atomic layer deposition, physical vapor deposition, sputtering, chemical solution deposition and plating.

20. The method of claim 16 further comprises a forming a plating seed layer located between said conductive material and said diffusion barrier, said plating seed layer comprises Cu, A Cu alloy, Ir, an Ir alloy, Ru or a Ru alloy.

21. The method of claim 20 wherein said plating seed layer is formed by chemical vapor deposition, plasma enhanced chemical vapor deposition, atomic layer deposition or physical vapor deposition.

22. The method of claim 16 wherein said conductive material comprises Cu, W or Al in pure or alloyed form.

23. The method of claim 16 wherein said partially filing the at least one opening with the conductive material comprises a deposition process selected from chemical vapor deposition, sputtering, chemical solution deposition and plating.

24. The method of claim 16 wherein said partially filing the at least one opening with the conductive material comprises completely filling the at least one opening with said conductive material and recessing.

25. The method of claim 16 wherein said insulating or metallic material having diffusion barrier properties comprises one of silicon carbide, silicon nitride, a nitrogen and hydrogen doped silicon carbide and a metallic material selected from Ta, Ru, Ir, W, Co, Ti and Rh in pure, alloyed or nitrided forms.
